(19) United States
(12) Patent Application Publication
(10) Pub. No.: US 2018/0233477 A1
(43) Pub. Date: Aug. 16, 2018

(54) ELECTRONIC PACKAGING STRUCTURE

(71) Applicant: INDUSTRIAL TECHNOLOGY RESEARCH INSTITUTE, Hsinchu (TW)

(72) Inventors: Jing-Yao Chang, Hsinchu (TW); Tao-Chih Chang, Hsinchu (TW); Fang-Jun Leu, Hsinchu (TW); Wei-Kuo Han, Hsinchu (TW); Kuo-Shu Kao, Hsinchu (TW)

(21) Appl. No.: 15/487,754

(22) Filed: Apr. 14, 2017

(30) Foreign Application Priority Data
Feb. 15, 2017 (TW) 106104871

(51) Int. Cl. H01L 23/00

(52) U.S. Cl. CPC H01L 24/29; H01L 24/32; H01L 2224/26155; H01L 2924/014; H01L 2924/0665; H01L 2224/29139; H01L 2924/10272; H01L 2224/29147; H01L 2224/29155; H01L 2224/32503; H01L 2224/32258; H01L 2924/3512; H01L 2224/29144

(57) ABSTRACT

An electronic package structure is provided. The electronic packaging structure includes a substrate, a conductive layer disposed on the substrate, an intermetallic compound disposed on the conductive layer, a stress buffering material and an electronic device. The stress buffering material is disposed on the substrate and adjacent to the conductive layer. The electronic device is disposed on the intermetallic compound and the stress buffering material, and the electronic device is in contact with the intermetallic compound. The stress buffering material is adjacent to the conductive layer to have the conductive layer and the stress buffering material together serving as a stress buffer, so as to enhance the effect of stress buffering, thereby preventing a wafer from cracking due to stress.

### CROSS-REFERENCE TO RELATED APPLICATION

This application claims the priority benefits of Taiwan application serial no. 106104871, filed on Feb. 15, 2017. The entirety of the above-mentioned patent application is hereby incorporated by reference herein.

### TECHNICAL FIELD

The technical field relates to an electronic packaging structure, and a technique improving the reliability thereof.

### BACKGROUND

With the flourishing development of the electronic industry, electronic products are facing gradually towards multi-functional and high-performance trends. Currently used in the technologies of chip packaging are such as chip scale package (CSP), direct chip attached (DCA), the flip-chip typed packaging module of multi-chip module (MCM), and the wafer stacking technology of 3-dimensional integrated circuits (3DIC).

In known technologies of semiconductor packaging, for example, wire bonding packaging technique is shown in FIG. 1. A semiconductor packaging structure 1 comprises an inactive surface 14b of a semiconductor wafer 14 bonded with a pad 100 of a package substrate 10 through a bonding layer 11. Electrodes 140 of an active surface 14a of the semiconductor wafer 14—are electrically connected to a wiring layer 101 of the package substrate 10 by using the aforesaid wire bonding process to form a plurality of wires 15. Thereafter, the package substrate 10 may be electrically connected to a circuit board (not shown) or an external device (not shown) by a solder ball (not shown) formed on the bottom side of the package substrate 10.

The general semiconductor packaging structure 1 is operating at high temperatures with a severe Creep effect. This does not facilitate to maintain the mechanical strength of the solder bonding, thereby failing to meet the reliability required by the module. The mechanical stress is another cause of damage to the module. Therefore, after the semiconductor wafer 14 is bounded with the bonding layer 11, the ability to withstand thermal stress and mechanical stress between the semiconductor wafer 14 and the bonding layer 11 becomes weaker. Specifically, a cracked position k is at the bonding position of an outer edge of the semiconductor wafer 14, as shown in FIG. 1.

Therefore, how to overcome the existing problems of known technologies is one of important issues.

### SUMMARY

An exemplary embodiment of the disclosure relates to an electronic packaging structure. The electronic packaging structure includes a substrate, a conductive layer disposed on the substrate, an intermetallic compound disposed on the conductive layer, a stress buffering material and an electronic device. The stress buffering material is disposed on the substrate and adjacent to the conductive layer. The electronic device is disposed on the intermetallic compound and the stress buffering material, and the electronic device is in contact with the intermetallic compound.

The foregoing will become better understood from a careful reading of a detailed description provided herein below with appropriate reference to the accompanying drawings.

### BRIEF DESCRIPTION OF THE DRAWINGS

FIG. 1 is a cross-sectional schematic view of a general semiconductor packaging structure.

FIG. 2 is a cross-sectional schematic view of an electronic packaging structure according to an embodiment of the disclosure.

FIG. 2′ is a bottom schematic view of the electronic packaging structure of FIG. 2.

FIG. 3 is a cross-sectional schematic view of an electronic packaging structure according to another embodiment of the disclosure.

FIG. 3′ is a bottom schematic view of an electronic packaging structure of FIG. 3.

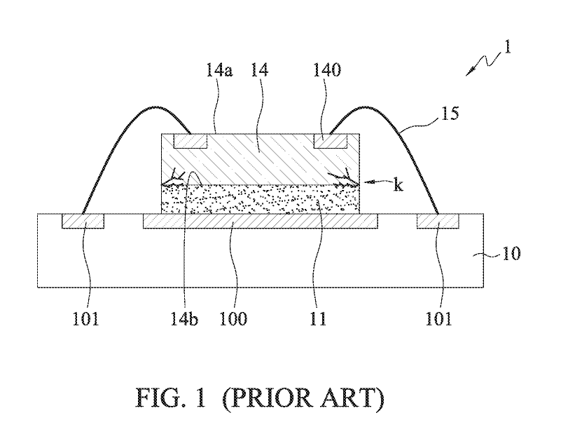

### DESCRIPTION OF THE EMBODIMENTS

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

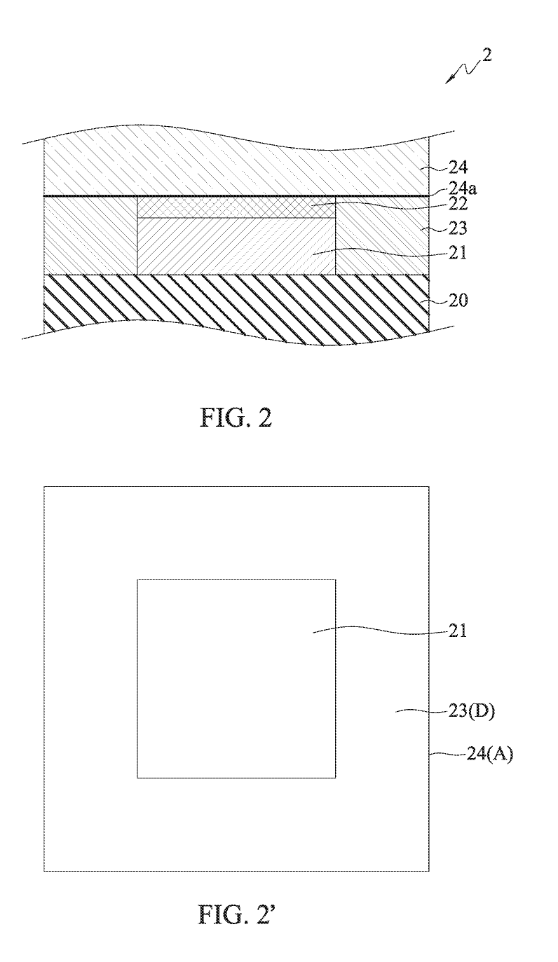

FIG. 2 is a cross-sectional schematic view of an electronic packaging structure according to an embodiment of the disclosure. Referring to FIG. 2, in the embodiment, an electronic packaging structure 2 comprises a substrate 20, a conductive layer 21, an intermetallic compound (IMC) 22, a stress buffering material 23 and an electronic device 24.

The substrate 20 is a metal board such as a gold board, a silver board, a copper board or a nickel board.

The conductive layer 21 is disposed on the substrate 20 and comprises a metal material. In the embodiment, the metal material is, for example, silver. The conductive layer 21 is a silver layer of various states. In other embodiments, the metal material of the conductive layer 21 may be, but not limited to gold, copper, nickel or other metal materials. However, the material of the conductive layer 21 is not limited thereto, and the material of the conductive layer 21 only need to meet the characteristics of the low thermal resistance and/or high thermal conductivity, low impedance, low temperature assembly and/or high temperature applications, high temperature resistant (greater than 400° C.) and so on. The material of the conductive layer 21 and the substrate 20 may be the same or different.

The intermetallic compound 22 is disposed on the conductive layer 21. In the embodiment, the intermetallic compound 22 is a structure generated between the electronic component 24 and the conductive layer 21 after the electronic device 24 is thermally bonded with (solder bonded) the conductive layer 21. Therefore, the material of the intermetallic compound 22 depends on the solder material of the stress buffering material 23.

The stress buffering material 23 is disposed on the substrate 20 and adjacent to the conductive layer 21. Also, the stress buffering material 23 may be adjacent to the intermetallic compound 22. In the manufacture processing, the stress buffering material 23 is coated with the side surface and the top surface of the conductive layer 21. After the electronic device 24 is disposed on the stress buffering material 23, the electronic device 24 is bonded with the stress buffering material 23 by a thermal compression bonding. And the stress buffering material 23 on the top surface of the conductive layer 21 reacts with the conductive layer 21 and a metal layer 24a on the back of the electronic device 24 to form the intermetallic compound 22 to bond with the electronic device 24. The material of the metal layer 24a is, for example, nickel, copper, silver or other weldable metal materials to bond with the soldering material used of the stress buffering material 23.

In the embodiment, the stress buffering material 23 comprises a solder, such as lead-free solder, high-temperature solder and so on.

Furthermore, the stress buffering material 23 surrounds the side surface of the conductive layer 21. Also, based on requirements, the stress buffering material 23 may surround the side surface of the intermetallic compound 22.

The electronic device 24 is disposed on the intermetallic compound 22 and the stress buffering material 23, and the electronic device 24 is in contact with the intermetallic compound 22. Also, based on requirements, the electronic device 24 may be in contact with the stress buffering material 23.

In the embodiment, the electronic device 24 is a semiconductor device. Take a SiC power semiconductor device as an example, the electronic device 24 may be, for example, metal-oxide-semiconductor field-effect transistor (MOSFET), insulated gate bipolar transistor (IGBT), junction field-effect transistor (JFET) or diode.

Furthermore, the electronic device 24 uses the intermetallic compound 22 and the conductive layer 21 as a ground path or a heat dissipation path.

In addition, an area D of the stress buffering material 23 within a frontal projected area A of the electronic device 24 ranges from 1% to 50% of the frontal projected area A, as shown in FIG. 2 and FIG. 2′.

In the electronic packaging structure 2, the conductive layer 21 may serve as a heat dissipation, while the stress buffering material 23 may also serve as a stress buffer, wherein the side surface of the conductive layer 21 is surrounded by the stress buffering material 23 to avoid stress is transmitted to the side of the electronic device 24. Therefore, compared with known arts, the electronic package structure 2 may enhance the effect of stress buffering in order to effectively prevent the electronic device 24 from being cracked from its side wall due to the stress such as a stress known from the thermal stress of the motor.

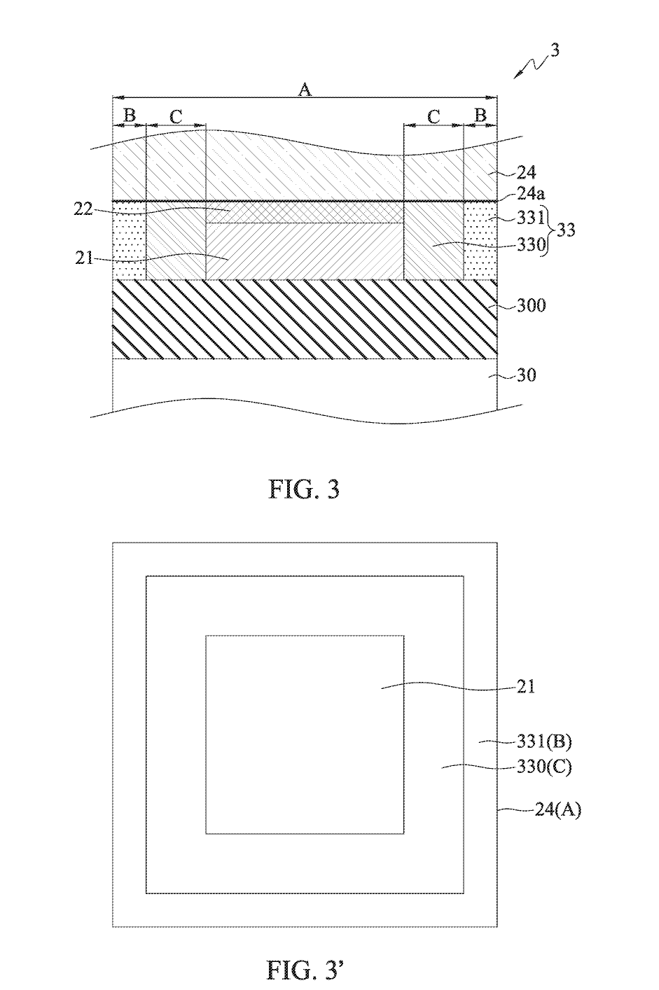

FIG. 3 is a cross-sectional schematic view of an electronic packaging structure according to another embodiment of the disclosure. The embodiment of FIG. 3 is similar to the embodiment of FIG. 2. Like reference numerals refer to like elements, and the same description will not be repeated herein. The difference between the two embodiments is the design of the substrate and the stress buffering material.

Referring to FIG. 3, in the embodiment, an electronic packaging structure 3 comprises a substrate 30 and a stress buffering material 33. The substrate 30 has a bonding pad 300 for bonding with the conductive layer 21. The stress buffering material 33 comprises a solder 330 and an organic material 331.

The bonding pad 300 is a metal pad such as a copper pad. The substrate 30 has a wire layer (not shown) electrically connected or not electrically connected to the bonding pad 300, which may depend on requirements.

In the embodiment, the material of the substrate 30 is a ceramic material or an organic material such as a glass fiber resin, a dielectric material, a printed circuit board and so on. However, the material of the substrate 30 is not limited thereto.

The organic material 331 is an insulating material such as silicone or epoxy-based material.

In the embodiment, wherein a sum (B+C) of the area B of the organic material 331 and the area C of the solder 330 within a frontal projected area A of the electronic device 24 ranges from 1% to 50% of the frontal projected area A, as shown in FIG. 3 and FIG. 3′.

In the electronic packaging structure 3, the conductive layer 21 may serve as a heat dissipation, while the stress buffering material 33 may also serve as a stress buffer, wherein the side surface of the conductive layer 21 is surrounded by the stress buffering material 33 to avoid stress is transmitted to the side of the electronic device 24. Therefore, compared with known arts, the electronic package structure 3 may enhance the effect of stress buffering in order to effectively prevent the electronic device 24 from being cracked from its side wall due to the stress such as a stress known from the thermal stress of the motor.

As aforesaid, in the embodiments of the electronic packaging structure of the present disclosure, the stress buffering material is adjacent to the conductive layer to have the conductive layer and the stress buffering material together serving as a stress buffer. This may effectively prevent the electronic device from being cracked by the stress so as to enhance the effect of the stress buffer, thereby improving the reliability of the electronic packaging structure.

It will be apparent to those skilled in the art that various modifications and variations can be made to the present disclosure. It is intended that the specification and examples be considered as exemplary embodiments only, with a scope of the disclosure being indicated by the following claims and their equivalents.

1. An electronic packaging structure, comprising:
a substrate;
a conductive layer disposed on the substrate;
an intermetallic compound disposed on the conductive layer;
a stress buffering material disposed on the substrate and adjacent to the conductive layer;
a metal layer disposed on the intermetallic compound and the stress buffering material, wherein the metal layer is in direct contact with the intermetallic compound; and
an electronic device disposed on the metal layer.

2. The electronic packaging structure as claimed in claim 1, wherein the substrate is a metal board.

3. The electronic packaging structure as claimed in claim 1, further comprising at least one bonding pad bonding the substrate to the conductive layer.

4. The electronic packaging structure as claimed in claim 1, wherein the conductive layer comprises a metal material.

5. The electronic packaging structure as claimed in claim 4, wherein the metal material is gold, silver, copper or nickel.

6. The electronic packaging structure as claimed in claim 1, wherein the stress buffering material comprises a solder.

7. The electronic packaging structure as claimed in claim 6, wherein the stress buffering material further comprises an organic material.

8. The electronic packaging structure as claimed in claim 7, wherein a sum of an area of the organic material and an area of the solder within a frontal projected area of the electronic device ranges from 1% to 50% of the frontal projected area.

9. The electronic packaging structure as claimed in claim 1, wherein the conductive layer is surrounded by the stress buffering material.

10. The electronic packaging structure as claimed in claim 1, wherein the electronic device is a semiconductor device.

11. The electronic packaging structure as claimed in claim 1, wherein an area of the stress buffering material within a frontal projected area of the electronic device ranges from 1% to 50% of the frontal projected area.
